(19) United States
(12) Patent Application Publication
(10) Pub. No.: US 2024/0402619 A1
(43) Pub. Date: Dec. 5, 2024

(54) METHOD FOR GENERATING LEARNING MODEL FOR PREDICTING SEMICONDUCTOR DEVICE STRUCTURE AND APPARATUS FOR PREDICTING SEMICONDUCTOR DEVICE STRUCTURE

(71) Applicant: SAMSUNG ELECTRONICS CO., LTD., Suwon-si (KR)

(72) Inventors: Minkyu KIM, Suwon-si (KR); QHwan KIM, Suwon-si (KR); Ami MA, Suwon-si (KR); Sunghee LEE, Suwon-si (KR); Kyu-Baik CHANG, Suwon-si (KR); Jaehoon JEONG, Suwon-si (KR); Wanju CHO, Suwon-si (KR); Hanlim CHOI, Suwon-si (KR)

(73) Assignee: SAMSUNG ELECTRONICS CO., LTD., Suwon-si (KR)

(21) Appl. No.: 18/404,626

(22) Filed: Jan. 4, 2024

(30) Foreign Application Priority Data
Jun. 5, 2023 (KR) 10-2023-0072214

(51) Int. Cl. G03F 7/00

(52) U.S. Cl. CPC G03F 7/706841

(57) ABSTRACT

An apparatus for predicting a structure of a semiconductor device, the apparatus includes: at least one processor; a storage configured to store a learned model configured to predict the structure of the semiconductor device; and a memory configured to store at least one code, and at least one processor operatively connected to the memory and configured to execute the at least one code to: input non-destructive metrology data measured from the semiconductor device into the learned model, and predict the structure of the semiconductor device, based on the learned model, wherein the learned model is trained with training data including first data which is non-destructive metrology data and second data which is structural metrology data as reference data of the first data, and wherein the training data is refined based on a similarity of the training data in a space having a first axis corresponding to the first data and a second axis corresponding to the second data as reference axes.

### CROSS-REFERENCE TO RELATED APPLICATIONS

This application is based on claims priority under 35 U.S.C. § 119 to Korean Patent Application No. 10-2023-0072214, filed on Jun. 5, 2023, in the Korean Intellectual Property Office, the disclosure of which is incorporated by reference herein in its entirety.

### BACKGROUND

### 1. Field

Embodiments of the disclosure described herein relate to a method of generating a learning model predicting a structure of a semiconductor device and an apparatus for predicting the structure of the semiconductor device.

### 2. Description of the Relate Art

Various manufacturing processes are performed for the production of semiconductor devices. The shape of a semiconductor device may be changed according to process changes applied in various manufacturing processes.

As methods of analyzing the structure or the shape of a semiconductor device, there are methods of analyzing data measured from a semiconductor device based on a spectrum or analyzing an analysis sample such as an electron microscope image.

A method of analyzing data measured from the semiconductor device based on the spectrum is a non-destructive method and may be applied during a process. However, in this method, a training of a structure prediction model based on a sample for analysis needs precede the method of analyzing the data. Moreover, overfitting may occur due to some inappropriate data.

### SUMMARY

Provided are a method of generating a learning model predicting a structure of a semiconductor device based on training data having improved consistency and an apparatus for predicting the structure of the semiconductor device.

According to an aspect of the disclosure, an apparatus for predicting a structure of a semiconductor device, the apparatus includes: at least one processor; a storage configured to store a learned model configured to predict the structure of the semiconductor device; and a memory configured to store at least one code, and at least one processor operatively connected to the memory and configured to execute the at least one code to: input non-destructive metrology data measured from the semiconductor device into the learned model, and predict the structure of the semiconductor device, based on the learned model, wherein the learned model is trained with training data including first data which is non-destructive metrology data and second data which is structural metrology data as reference data of the first data, and wherein the training data is refined based on a similarity of the training data in a space having a first axis corresponding to the first data and a second axis corresponding to the second data as reference axes.

According to an aspect of the disclosure, a method of generating a learned model configured to predict a structure of a semiconductor device, includes: identifying training data including: first data which is non-destructive metrology data of the semiconductor device, and second data which is structure data as reference data of the first data; refining the training data based on a similarity of the training data in a first space having a first axis corresponding to the first data and a second axis corresponding to the second data as first reference axes; and training a learning model based on the refined training data.

According to an aspect of the disclosure, an apparatus of generating a learning model configured to predict a structure of a semiconductor device, includes: a memory configured to store at least one code; and at least one processor operatively connected to the memory and configured to execute the at least one code to: train the learning model with training data including: first data which is non-destructive metrology data measured from the semiconductor device, and second data which is structure data as reference data of the first data, and refine the training data based on a similarity of the training data in a first space having a first axis corresponding to the first data and a second axis corresponding to the second data as first reference axes.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 illustrates an apparatus predicting a structure of a semiconductor device, according to an embodiment of the disclosure;

FIG. 2 illustrates a configuration of an apparatus predicting a structure of a semiconductor device, according to an embodiment of the disclosure;

FIG. 3 illustrates an operating method of an apparatus predicting a structure of a semiconductor device, according to an embodiment of the disclosure;

FIG. 4 illustrates a configuration of an apparatus generating a learning model predicting a structure of a semiconductor device, according to an embodiment of the disclosure;

FIG. 5 illustrates a training method of a learning model predicting a structure of a semiconductor device, according to an embodiment of the disclosure;

FIG. 6 illustrates a method of refining training data for training a learning model predicting a structure of a semiconductor device, according to an embodiment of the disclosure;

FIGS. 7A to 7G illustrate a method for refining training data, according to an embodiment of the disclosure;

FIG. 8 illustrates a similarity determination method of training data, according to an embodiment of the disclosure;

FIG. 9 illustrates a user interface for refining training data having low similarity, according to an embodiment of the disclosure; and

FIGS. 10A and 10B illustrate experimental results of a learning model predicting a structure of a semiconductor device, according to an embodiment of the disclosure.

### DETAILED DESCRIPTION

Hereinafter, embodiments of the disclosure may be described in detail and clearly to such an extent that an ordinary one in the art easily implements the disclosure.

he description merely illustrates the principles of the disclosure. Those skilled in the art will be able to devise one or more arrangements that, although not explicitly described herein, embody the principles of the disclosure. Furthermore, all examples recited herein are principally intended expressly to be only for explanatory purposes to help the reader in understanding the principles of the disclosure and the concepts contributed by the inventor to furthering the art and are to be construed as being without limitation to such specifically recited examples and conditions. Moreover, all statements herein reciting principles, aspects, and embodiments of the disclosure, as well as specific examples thereof, are intended to encompass equivalents thereof.

Terms used in the present disclosure are used only to describe a specific embodiment, and may not be intended to limit the scope of another embodiment. A singular expression may include a plural expression unless it is clearly meant differently in the context The terms used herein, including a technical or scientific term, may have the same meaning as generally understood by a person having ordinary knowledge in the technical field described in the present disclosure. Terms defined in a general dictionary among the terms used in the present disclosure may be interpreted with the same or similar meaning as a contextual meaning of related technology, and unless clearly defined in the present disclosure, it is not interpreted in an ideal or excessively formal meaning. In some cases, even terms defined in the present disclosure cannot be interpreted to exclude embodiments of the present disclosure.

In one or more embodiments of the disclosure described below, a hardware approach is described as an example. However, since the one or more embodiments of the disclosure include technology that uses both hardware and software, the various embodiments of the present disclosure do not exclude a software-based approach.

In addition, in the disclosure, in order to determine whether a specific condition is satisfied or fulfilled, an expression of more than or less than may be used, but this is only a description for expressing an example, and does not exclude description of more than or equal to or less than or equal to. A condition described as ‘more than or equal to’ may be replaced with ‘more than’, a condition described as ‘less than or equal to’ may be replaced with ‘less than’, and a condition described as ‘more than or equal to and less than’ may be replaced with ‘more than and less than or equal to’. In addition, hereinafter, ‘A’ to ‘B’ means at least one of elements from A (including A) and to B (including B).

The terms “include” and “comprise”, and the derivatives thereof refer to inclusion without limitation. The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” refers to any device, system, or part thereof that controls at least one operation. Such a controller may be implemented in hardware or a combination of hardware and software and/or firmware. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. The expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

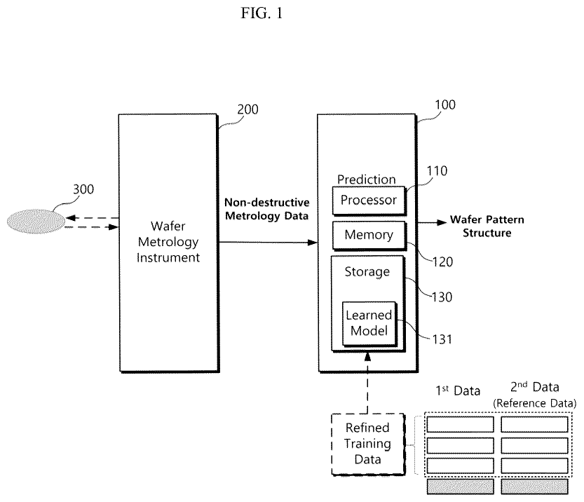

FIG. 1 is a diagram illustrating an apparatus 100 for predicting a structure of a semiconductor device according to an embodiment of the disclosure and an application environment.

According to an embodiment of the disclosure, the apparatus 100 (also called “prediction apparatus”) for predicting the structure of the semiconductor device is configured to predict the structure of the semiconductor device using a learned model. Training data of the learned model is refined based on the similarity of the training data that includes first data and second data (that is reference data of the first data). Based on the similarity of the first data in consideration of the second data, the training data having a low similarity is excluded from a final set of training data. The training data may be refined based on the similarity of the training data in a space having a first axis ‘based on’ (corresponding to) the first data and a second axis ‘based on’ (corresponding to) the second data as reference axes. Thanks to the training data with improved similarity, in the prediction apparatus 100, a prediction accuracy of the structure of the semiconductor device is improved.

Referring to FIG. 1, the prediction apparatus 100 includes a processor 110, a memory 120, and a learned model 131. Throughout the disclosure, the processor 110 refers to one or more processors or at least one processor. In FIG. 1, the processor 110 may be replaced with multiple processors.

Semiconductor devices, such as logic and memory devices, are manufactured by a plurality of manufacturing processes applied to a substrate or a wafer 300. Various features, a plurality of structures, and shapes of a semiconductor device are formed based on at least one process among the plurality of manufacturing processes.

A wafer metrology instrument 200 measures the wafer 300 using various methods such as non-destructive metrology methods such as optical metrology, electromagnetic metrology, and X-ray based metrology. The wafer metrology instrument 200 radiates at least one of light signals, electromagnetic waves, and X-rays, which are sources for metrology to the wafer 300. The wafer metrology instrument 200 observes and analyzes at least one of the light signals, the electromagnetic waves, and the X-rays obtained when the irradiated metrology source is radiated from the wafer 300 based on at least one phenomenon of reflection, transmission, scattering, and diffraction to generate a metrology value. In an embodiment, the wafer metrology instrument 200 includes or corresponds to any or all of various types of metrology devices that obtain metrology data by non-destructively irradiating at least one of the light signals, the electromagnetic waves, and the X-rays onto the wafer 300. Thus, wafer metrology instrument 200 is not particularly limited to any type of the metrology devices.

The wafer metrology instrument 200 may be a spectroscopic ellipsometry or a spectroscopic reflectometry. The wafer metrology instrument 200 may be a form of (or may relate to or perform) a scatterometry or a reflectometry. The wafer metrology instrument 200 may be a form of an X-ray based scatterometry or an X-ray based reflectometry. The wafer metrology instrument 200 may be an optical critical dimension metrology instrument.

The wafer metrology instrument 200 includes an analysis algorithm of at least one of the light signals, the electromagnetic waves, and the X-rays radiated along with optical structures and electromagnetic instrumentation structures for scatterometry, reflectometry, and ellipsometry. The wafer metrology instrument 200 outputs various structural or morphological parameters of critical dimension, film thickness, band gap, composition, overlay, and nanoscale structure of a semiconductor device as metrology data. The metrology data of the wafer metrology instrument 200 may be in a spectral form.

The metrology data may be one of a variety of parameters depending on a type of the wafer metrology instrument 200 and the metrology source.

For example, metrology data of ellipsometry may include a plurality of ellipsometric parameters over a spectral range obtained from a metrology area of the wafer 300.

The wafer metrology instrument 200 may provide metrology data (obtained by measuring the wafer 300) to the prediction apparatus 100 via online (e.g., in real time) or an offline file. The metrology data is non-destructive metrology data.

The prediction apparatus 100 according to an embodiment of the disclosure predicts the structure of the semiconductor device by inputting the metrology data provided from the wafer metrology instrument 200 to the learned model 131.

The memory 120 of the prediction apparatus 100 is configured to store a ‘code’ that causes the processor 110 to perform an operation. The ‘code’ refers to a set of instructions loaded into the memory 120.

The processor 110 is configured to load the learned model 131 from a storage 130. The processor 110 is configured to apply various weighting parameters of the learned model 131 to metrology data that is input data. The processor 110 is configured to generate an output value from values calculated based on the weighting parameters.

In one embodiment, the learned model 131 may be a deep learning based model having a plurality of layers including a neural network. In an embodiment, the learned model 131 may be a machine learning based model. A training of the learned model 131 may be executed or completed based on training data.

According to an embodiment of the disclosure, the structure of the semiconductor device, predicted by the prediction apparatus 100 based on the learned model 131 may be a length, width, etc. related to morphological, structural, and geometric shapes of at least a portion of the pattern of the semiconductor device.

The structure of the semiconductor device, which is predicted by the prediction apparatus 100, may include all numerical values measurable in each of several manufacturing processes of the semiconductor device.

For example, the structure of the semiconductor device may be a numerical value related to any one structural shape (of various types of patterns) such as a thickness of a thin film, a recess height, a thickness or width of a pattern, a profile height, a sidewall angle, a pitch, a middle critical dimension (MCD), various critical dimensions (critical dimension of top, middle, bottom, neck etc.), a channel hole height/radius, a mask height, etc.

The learned model 131 is trained with training data including metrology data measured by the wafer metrology instrument 200 in each of several manufacturing processes and reference data, which are numerical values related to a shape. The reference data may be referred to as ‘labeling data’ with respect to the metrology data.

For example, the learned model 131 may be trained with training data including a spectrum measured after performing a thin film deposition process and the thickness of a thin film as the reference data.

For example, the learned model 131 may be trained with training data including a spectrum measured after performing an etching process and an etch depth or width as reference data.

The structure of the semiconductor device, which is reference data, may be measured using, for example, transmission electron microscopy (TEM), scanning electron microscopy (SEM), atomic force microscopy (AFM), with respect to a sample for analysis after any or each of the several manufacturing processes is performed.

The reference data may be collected from samples for analysis prepared in a destructive manner after each manufacturing process is performed. The reference data may be structure data measured on at least a part of a region of the wafer 300 from which metrology data is collected. The sample for analysis may be a sample for at least a part of a region of the wafer 300 from which metrology data is collected.

According to an embodiment of the disclosure, the training data of the learned model 131 is refined based on the similarity of the training data. The training data is refined based on the similarity of the metrology data for which the reference data is considered. In an embodiment, the training data is refined in a space having a first axis (based on the reference data) and a second axis (based on the metrology data) as reference axes.

The training data may be refined based on, for example, the similarity of trends, the similarity of distribution directions between the metrology data for which the reference data is considered.

The similarity of the metrology data for which the reference data is considered may be determined based on a distribution tendency of a plurality of pieces of metrology data for which the reference data is considered.

The similarity of the metrology data for which the reference data is considered may be determined based on the similarity between a plurality of pieces of training data located in a space having an axis based on the metrology data and an axis based on the reference data as reference axes of the space.

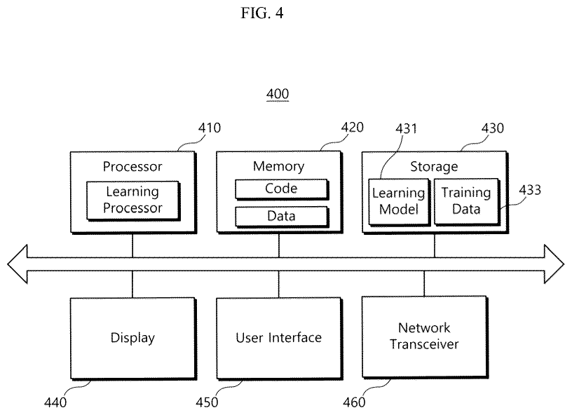

Refinement of the training data may be performed by a ‘learned model generating apparatus’ described with reference to FIG. 4.

For example, when a linear tendency exists among metrology data for which the reference data is considered, the learning model generating apparatus may exclude, from the final set of the training data, training data that is out of a range of the preset linear tendency.

In an embodiment, when a linear tendency exists between the metrology data for which the reference data is considered, the learning model generating apparatus may visualize the linear tendency. The learned model generating apparatus may receive a user's input for the visualized result, and may exclude, from the final set of the training data, some training data based on the user's input.

In the related art, a learned model for predicting the structure of the semiconductor device is trained by refined training data depending on user's empirical knowledge. Alternatively, in the related art, the learning model is trained by refined training data based only on the characteristics of metrology data such as spectrum data.

In detail, in the related art, the learning model is trained with refined training data based on the analysis value of the metrology data after analyzing metrology data such as spectrum data measured from the semiconductor device. Such techniques in the related art are based only on the characteristics of spectrum metrology data in which the reference data is not reflected. The techniques in the related art refine training data in a space composed only of axes based on metrology data. Therefore, the techniques in the related art use reference data only in a parameter training process of the learning model. As a result, training data (anomaly values) with low similarity is not excluded from training of the learning model in the related art, and at least a part of the characteristics of the anomaly values are reflected in the parameters of the learning model. Thus, in the related art, the predictive accuracy of the learning model is also lowered.

In contrast, the learned model 131 of the prediction apparatus 100 according to an embodiment of the disclosure is trained with refined training data based on the characteristics of the metrology data in which the reference data is reflected. The prediction apparatus 100 predicts the structure of the semiconductor device based on the learned model 131. The training data of the learned model 131 is refined based on the similarity between the training data in a space having a first axis based on the metrology data and a second axis based on the reference data as reference axes of the space.

Thus, the learned model 131 of the prediction apparatus 100 according to an embodiment of the disclosure is trained by the training data in which anomaly values are excluded in consideration of the reference data. The training data in which anomaly values are excluded in consideration of the reference data has high similarity among the training data. As a result, the characteristic of the anomaly values is not reflected in the final parameter of the learned model 131 according to the embodiment of the disclosure. Thus, the learned model 131 is not over-fitted even when it is based on a small number of pieces of training data, and the prediction accuracy of the learned model 131 for the structure of the semiconductor device is also improved.

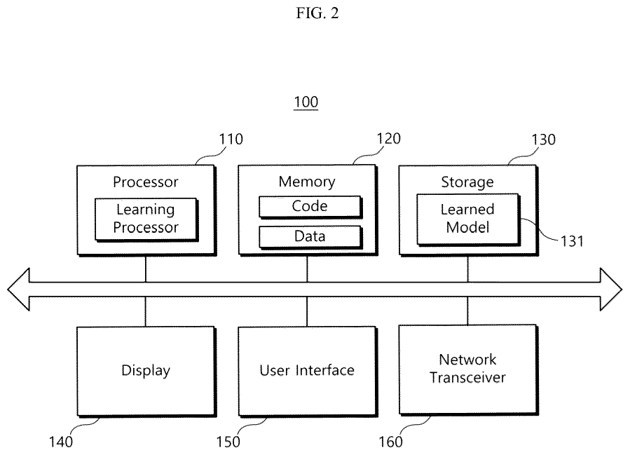

FIG. 2 is a block diagram illustrating a configuration of an apparatus 100 for predicting the structure of the semiconductor device, according to an embodiment of the disclosure.

The prediction apparatus 100 predicts the structure of the semiconductor device based on the learned model 131. The learned model 131 is trained with refined training data by reflecting the characteristics of the metrology data and the characteristics of the reference data. The learned model 131 is trained by refined training data based on the similarity of metrology data in which the reference data is considered. The training data of the learned model 131 is refined based on the similarity among a plurality of pieces of training data located in a space having a first axis based on the metrology data and a second axis based on the reference data as reference axes.

As shown in FIG. 2, the prediction apparatus 100 includes the processor 110, the memory 120, the storage 130, a display 140, a user interface 150, and a network transceiver 160. Code loaded and temporarily stored in the memory 120 causes the processor 110 to perform an operation.

The processor 110 is configured to load the learned model 131 from the storage 130. The processor 110 is configured to temporarily store metrology data received online or offline from the wafer metrology instrument 200 in the memory 120 and is configured to input the metrology data to the learned model 131.

The processor 110 may include an artificial intelligence-based learning processor that accelerates deep learning or machine learning operations. The learning processor may be a processor including a graphics processing unit (GPU), a tensor processor, a neural processing unit (NPU), and a digital signal processor (DSP). The processor 110 may be a processor coupled with a memory.

The processor 110 is configured to apply the weighting parameters of the learned model 131 based on deep learning to metrology data. The processor 110 is configured to input output values output from nodes of each layer of the learned model 131 to nodes of a subsequent layer based on a neural network structure. The processor 110 is configured to use the learned model 131 to output a structure, such as length and width, regarding the morphological, structural, and geometrical shapes of at least a portion of the pattern of the semiconductor device.

The processor 110 is configured to input metrology data to the learned model 131 based on machine learning. The learned model 131 is configured to predict a structure such as a length, width, and the like regarding the morphological, structural, and geometrical shapes of at least a portion of a pattern of the semiconductor device.

For example, in the case of the learned model 131 based on a decision tree, the processor 110 is configured to input a vector composed of at least some numerical values of the metrology data to a root node of the decision tree as an input vector. The learned model 131 is configured to output the structure of the semiconductor device based on the branched tree structure according to a determination criterion of each node of the decision tree.

For example, in the case of the learned model 131 based on deep learning, the processor 110 is configured to input a vector composed of at least some numerical values of the metrology data to each node of the input layer as an input vector. The learned model 131 is configured to output the structure of the semiconductor device based on a network structure of the neural network and weights.

The memory 120 may be configured to (temporarily) store codes for the operation of the prediction apparatus 100, data for the operation of the processor 110, a weighting parameter of the learned model 131, an intermediate operation result of the learned model 131, etc.

The storage 130 is configured to store the learned model 131 trained by the learning model generating apparatus. The storage 130 may include a computer-readable storage medium. The storage media includes all types of recording devices in which data that can be read by a computer is stored. The storage medium may include at least one of a hard disk drive (HDD), a solid state disk (SSD), a silicon disk drive (SDD), a ROM, a RAM, a CD-ROM, a magnetic tape, a floppy disk, and an optical data storage device.

The storage 130 may be configured to classify and store the learned model 131 into a plurality of learned models according to a learning time, a type of training data, or a structure of a semiconductor device to be predicted according to an embodiment. For example, different learned models trained with different training data that is composed of different metrology data and reference data of different semiconductor device structures may be stored in the storage 130. Different learned models 131 may be applied according to the metrology data.

The learned model 131 may correspond to a deep learning-based model having a plurality of layers having a neural network. The learned model 131 may correspond to a machine learning-based model.

The neural network of the learned model 131 may include at least one of Convolutional Neural Network (CNN), Region with Convolution Neural Network (R-CNN), Region Proposal Network (RPN), Recurrent Neural Network (RNN), Long Short-Term Memory (LSTM) Network, stacking-based deep neural network (S-DNN), state-space dynamic neural network (S-SDNN), deep belief network (DBN), and restricted Boltzmann machine (RBM), etc., and does not exclude other structures of the neural network structures.

The learned model 131 is a machine learning-based model, which may correspond to a model based on decision tree, association rule, genetic algorithm, inductive learning method, support vector machine (SVM), cluster analysis, Bayesian network, reinforcement learning method, regression model. The model does not exclude other structures of the machine learning-based structures.

The learned model 131 may be implemented in hardware, software, or a combination of hardware and software. When part or all of the learned model 131 is implemented with software, one or more commands constituting the learned model may be stored in the storage 130.

According to an embodiment of the disclosure, the learned model 131 is trained with refined training data by reflecting the characteristics of the metrology data and the characteristics of the reference data.

The learned model 131 is trained with training data including metrology data measured by the wafer metrology instrument 200 in each of several manufacturing processes and reference data of the metrology data.

The learned model 131 is trained with training data including non-destructive metrology data and structural metrology data that is reference data of the non-destructive metrology data.

In an embodiment, the training data of the learned model 131 is metrology data of the semiconductor device based on spectrum, which is non-destructive metrology data, and the reference data may be structure data obtained by directly measuring the length, width, height, etc. of at least a part of the structure of the semiconductor device through SEM, TEM, AFM, etc.

The training data of the learned model 131 is refined based on the similarity among non-destructive metrology data in which structure data that is reference data of the non-destructive metrology data is considered. The training data of the learned model 131 is training data refined in a space having a first axis based on structure data, which is reference data of non-destructive metrology data, and a second axis based on non-destructive metrology data as reference axes.

The display 140 is configured to display a result of predicting the structure of the semiconductor device by the prediction apparatus 100 using the learned model 131. The display 140 is not limited to a visual display, and may display a result based on visual, auditory, or tactile senses.

The user interface 150 includes an interface for receiving a user's input for controlling the prediction apparatus 100. The user interface 150 includes an interface that receives a user's input with respect to the output displayed on the display 140. The user interface 150 may include a graphical user interface (GUI) displayed on the display 140 and a touch input unit implemented on the display 140.

In an embodiment, the prediction apparatus 100 may receive metrology data from the wafer metrology instrument 200 online through the network transceiver 160. The network transceiver 160 may include at least one of a mobile communication module based on LTE (Long Term Evolution), LTE-A (Long Term Evolution-Advanced), etc., a wireless Internet module based on Wi-Fi, WLAN, etc., and a short-range communication module based on Bluetooth™, RFID (Radio Frequency Identification), infrared communication, UWB (Ultra Wideband), ZigBee, NFC (Near Field Communication), etc.

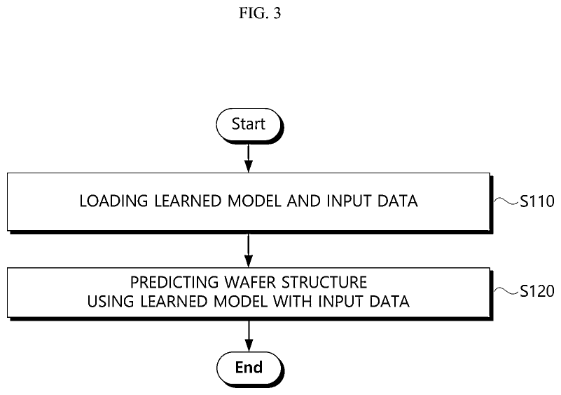

FIG. 3 is a flowchart illustrating an operating method of an apparatus for predicting a structure of a semiconductor device (also called as a ‘prediction apparatus’) according to an embodiment of the disclosure.

The prediction apparatus receives the learned model generated by the learned model generating apparatus online or offline.

The learned model receives metrology data obtained by measuring a wafer on which at least one pattern is generated through a wafer metrology instrument, and predicts a structure of a semiconductor device.

In an embodiment, the structure of the semiconductor device may be a length, width, height, etc. related to the morphological, structural, and geometric shapes of at least one pattern formed on a wafer by at least one semiconductor process. The structure of the semiconductor device may include all structural numerical values measurable in each of several manufacturing processes of the semiconductor device.

The prediction apparatus receives metrology data measured by the wafer metrology instrument online or offline.

In operation S110, the prediction apparatus loads the learned model and metrology data. Loading may refer to store at least a portion of various parameters constituting the learning model, such as a network structure parameter and a weight parameter of the learned model, and at least a portion of metrology data in a memory such as a DRAM, which is a temporary storage device.

In operation S120, the prediction apparatus predicts the structure of the semiconductor device by inputting the metrology data to the learned model trained with the refined training data by reflecting the characteristics of the metrology data and the characteristics of the reference data.

According to an embodiment of the disclosure, the training data of the learned model is refined based on the similarity of metrology data in which the reference data is considered. The training data of the learned model is refined in a space having a first axis based on reference data and a second axis based on metrology data as reference axes of the space.

Accordingly, according to an embodiment of the disclosure, the prediction apparatus may accurately predict the structure of the semiconductor device.

FIG. 4 is a block diagram illustrating a configuration of an apparatus (also called as a ‘learning apparatus’) 400 for generating a learned model for predicting the structure of the semiconductor device, according to an embodiment of the disclosure.

The learning apparatus 400 according to an embodiment of the disclosure trains a learning model that predicts the structure of the semiconductor device based on non-destructive metrology data. The learning apparatus 400 refines training data before training the learning model. The learning apparatus 400 refines the training data based on the similarity of the metrology data in which the reference data is considered. The learning apparatus 400 refines training data in a space having a first axis based on reference data and a second axis based on metrology data as reference axes.

A configuration of the learning apparatus 400 will be described in detail with reference to FIG. 4. Some of the configurations of the learning apparatus 400 may be similar to those of the prediction apparatus 100. Additional descriptions of parts similar to or overlapping with the previous description will be omitted to avoid redundancy.

The learning apparatus 400 is a variety of devices for training a learning model. In an embodiment, the learning apparatus 400 corresponds to a typical server device or a computer separately designed to perform training.

The learning apparatus 400 may be implemented with a single computer, a plurality of computer sets, a cloud computer, or a combination thereof.

A plurality of learning apparatuses 400 may include a learning apparatus set (or a cloud computer). At least one learning apparatus 400 included in the learning apparatus set may refine training data 433 and may train the learning model 431 through distributed processing.

The learning apparatus 400 includes a processor 410, a memory 420, a storage 430, a display 440, a user interface 450, and a network transceiver 460.

The processor 410 is configured to load the untrained learning model 431 from the storage 430. For example, when based on a neural network, the learning model 431 may be a learning model in which values of at least some parameters including weight parameters among nodes of each layer are not determined.

The processor 410 is configured to temporarily store at least a portion of the training data 433 in the memory 420. The processor 410 is configured to input training data to the learning model 431 and to train the learning model 431 by changing a weight parameter value between each node of the learning model.

In an embodiment, the processor 410 may include an artificial intelligence-based learning processor that accelerates deep learning or machine learning operations.

In an embodiment, the processor 410 refines the training data before training the learning model.

The memory 420 may temporarily store codes for operation of the processor 410 and the learning apparatus 400, a weighting parameter of the learning model 431, intermediate calculation results during learning of the learning model 431, etc.

The storage 430 includes a computer-readable storage medium such as the HDD or the SDD, and may store the learning model 431 before training and a learned model after training. The storage 430 stores training data 433 for training the learning model.

The learning model 431 may be a deep learning-based learning model composed of a plurality of layers including a neural network or a machine learning-based learning model.

According to an embodiment of the disclosure, the display 440 may display a learning result of the learning model 431, a process of refining the training data 433, and a visualization result of the training data being refined. Visualization of the training data being refined may refer to display the distribution of the training data. Visualization of the training data being refined may refer to display the distribution of the training data based on dimensionally reduced metrology data into a low-dimensional space during the refinement process. Visualization of the training data being refined may refer to display the distribution of the training data in a space a first axis based on reference data and a second axis based on metrology data as reference axes.

The display 440 may receive a touch input through the user interface 450. The user interface 450 may include a graphical user interface for user selection. The learning apparatus 400 may receive a user's input with respect to distribution visualization of the training data being refined through the user interface 450.

The learning apparatus 400 may transmit the learned model for which training is completed to an apparatus for predicting the structure of the semiconductor device through the network transceiver 460. Alternatively, the learning apparatus 400 may provide the learned model for which training is completed to an apparatus for predicting the structure of the semiconductor device in an offline method.

The processor 410 of the learning apparatus 400 according to an embodiment of the disclosure refines the training data 433 based on the similarity of the metrology data in which the reference data is considered. The processor 410 refines the training data in a space having a first axis (based on the reference data) and a second axis (based on the metrology data) as reference axes. Refinement of the training data is performed prior to training of the learning model 431. The learning model 431 is trained based on the refined training data. The training data 433 includes non-destructive metrology data and reference data based on the structure.

The training data 433 may be refined based on, for example, the similarity of trend, similarity of distribution direction, among metrology data in which reference data is considered. The training data 433 may be refined based, for example, on the similarity of trends, similarity of distribution directions of the training data in a space having the first axis based on the reference data and the second axis based on the metrology data as reference axes.

When there is similarity between the training data based on the linear tendency, the learning apparatus 400 may exclude the training data outside the preset range of the linear tendency from the final set of the training data.

The metrology data of the training data 433 may be dimensionally reduced into a low-dimensional space to determine similarity of trends and similarity of distribution directions between the training data. The processor 410 may refine the training data 433 based on the dimensionally reduced metrology data into a low-dimensional space. The processor 410 may refine the training data 433 in a space having a first axis (based on the reference data) and a second axis (based on the dimensionally reduced axis of the metrology data) as reference axes of the space.

The metrology data may be spectrum-based metrology data of a semiconductor device, and the reference data may be structure data obtained by measuring at least a part of a structure of the semiconductor device. The reference data may be, for example, length, width, height related to the morphological, structural, and geometric shapes of at least one pattern formed in each process. The structure data of the semiconductor device may include all structural numerical values measurable in each of several manufacturing processes of the semiconductor device.

The processor 410 is configured to perform training of the learning model 431 based on the refined training data.

Therefore, the learning model 431 according to an embodiment of the disclosure is trained based on training data from which training data having low similarity is excluded. Accordingly, overfitting of the learning model 431 may be prevented, and the learning model 431 may accurately predict the structure of the semiconductor device.

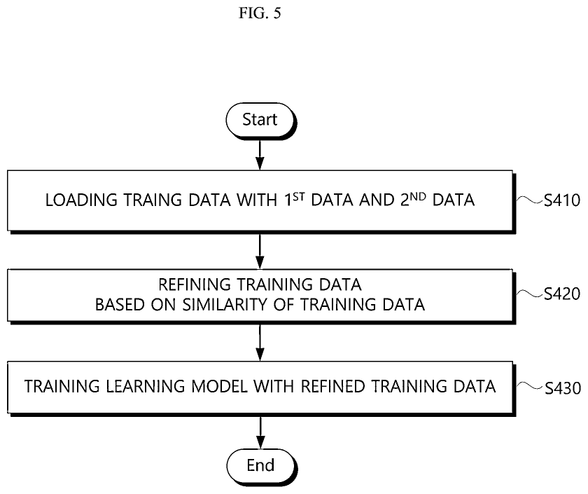

FIG. 5 is a flowchart illustrating an operating method of an apparatus (also called as a ‘learning apparatus’) generating a learned model for predicting a structure of a semiconductor device, according to an embodiment of the disclosure.

A learning apparatus according to an embodiment of the disclosure refines training data before training a learning model. The learning apparatus refines the training data based on the similarity of first data in which second data is considered. In one embodiment, the second data is reference data of the first data. The learning apparatus refines the training data based on the similarity of the training data in a space having a first axis (based on the first data) and a second axis (based on the second data) as reference axes.

In an embodiment, the learning apparatus refines training data including first data, which is metrology data of a semiconductor device based on spectrum, and second data, which is data obtained by measuring at least a part of a structure of a semiconductor device. The second data may be structure data of the semiconductor device measured in at least a part of the region where the first data is measured.

A method of operating a learning apparatus according to an embodiment of the disclosure will be described in detail with reference to FIG. 5. Additional descriptions of parts similar to or overlapping with those described above will be omitted to avoid redundancy.

In operation S410, the learning apparatus loads at least a part of the training data including the first data and the second data into the memory. The learning apparatus loads at least a portion of the learning model which is not untrained into the memory.

In operation S420, the learning apparatus according to an embodiment of the disclosure refines the training data based on the similarity of the first data in which the second data is considered. The learning apparatus refines the training data based on the similarity of the training data in a space having a first axis (based on the first data) and a second axis (based on the second data) as reference axes.

The similarity of the training data may be determined in a space having the first axis and the second axis as reference axes. The first axis is an axis based on a vector in a low-dimensional space in which the first data is dimensionally reduced. The second axis is an axis based on the second data.

In an embodiment, the similarity of the training data may be determined based on data obtained by projecting the first data to a search vector in a low-dimensional space in which the first data is dimensionally reduced.

The similarity may be a similarity of trend or a similarity of distribution direction in training data.

The learning apparatus determines a final set of the training data by determining the similarity in the training data and excluding the training data determined to be out of a preset similarity range.

In operation S430, the learning apparatus according to an embodiment of the disclosure trains a learning model using the final set of the training data (refined training data) from which training data with low similarity is excluded.

The learning apparatus may provide the learned model on which training is completed to an apparatus for predicting the structure of the semiconductor device in online or offline methods.

Thus, the learning apparatus according to an embodiment of the disclosure excludes training data having low similarity in the training process. Thus, overfitting of the learning model is prevented, and the learned model may accurately predict the structure of the semiconductor device.

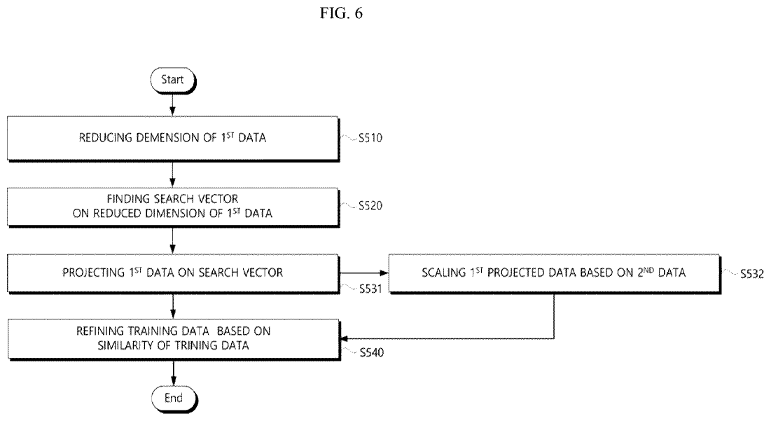

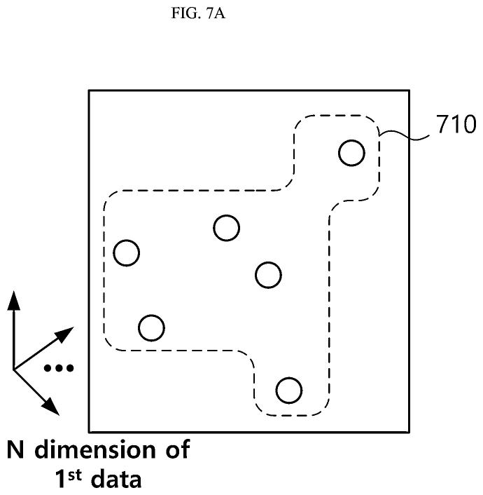

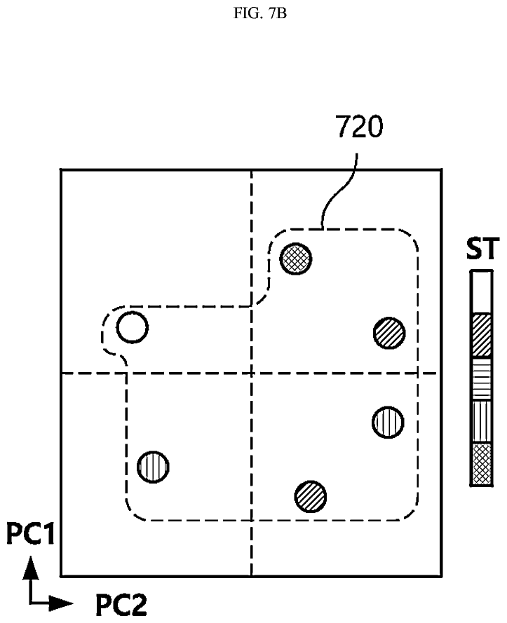

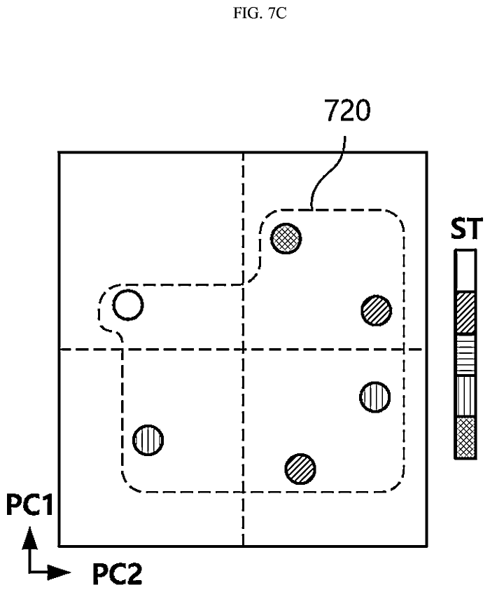

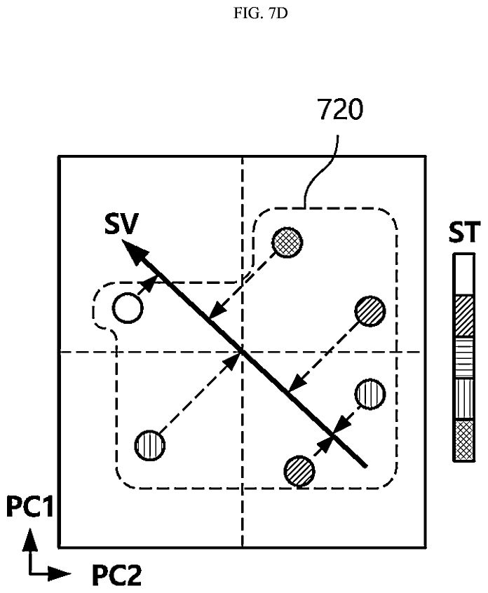

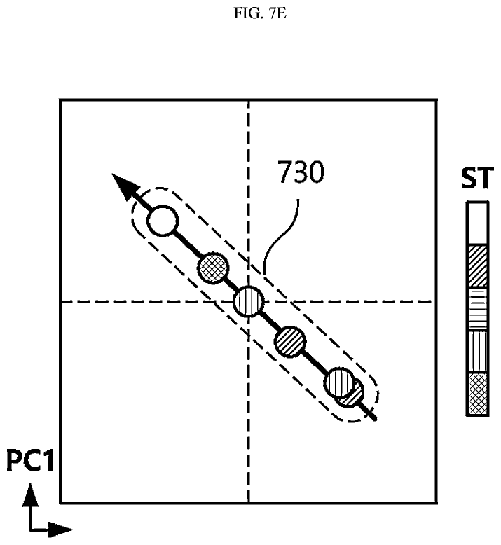

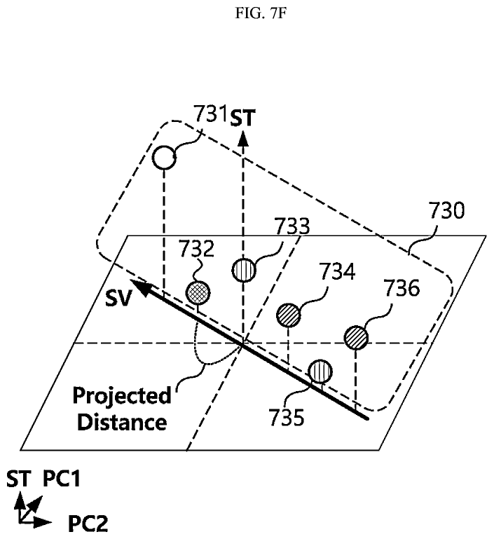

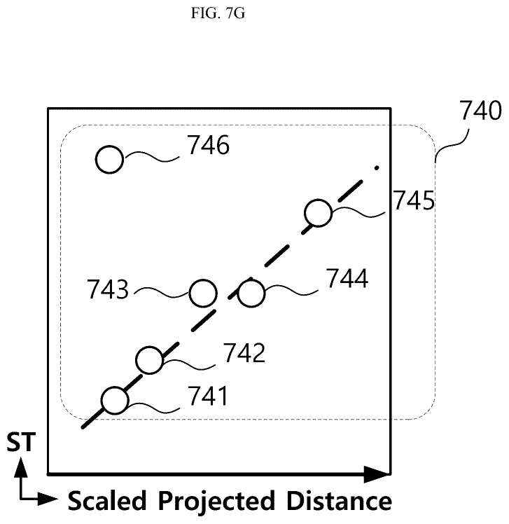

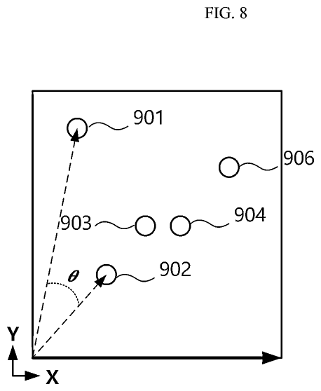

FIG. 6 is a flowchart illustrating a method of refining training data of an apparatus (also called as a ‘learning apparatus’) generating a learning model for predicting a structure of a semiconductor device according to an embodiment of the disclosure. FIG. 7 and FIG. 8 are diagrams describing in detail a method of refining training data.

The learning apparatus according to an embodiment of the disclosure refines the training data based on the similarity of the first data in which the second data is considered before the learning model is trained. The learning apparatus refines the training data based on the similarity of the training data in a space having a first axis (based on the first data) and a second axis (based on the second data) as reference axes of the space. The training data includes first data and second data that is reference data of the first data.

The method of refining training data according to an embodiment of the disclosure is not limited to spectrum-based metrology data and structure data that is reference data thereof. The description of the following embodiments will be described on the premise that the first data is spectrum-based metrology data of a semiconductor device and the second data is structure data of the semiconductor device. Additional descriptions of parts similar to or overlapping with those described above will be omitted to avoid redundancy.

In an embodiment, the training data includes first data and second data that is reference data of the first data. The first data may be metrology data of a semiconductor device based on spectrum. The second data may be data obtained by measuring at least a part of a structure of a portion of the wafer where the metrology data based on spectrum is measured.

The first data is spectrum-based metrology data and may be a vector having a plurality of spectrum parameters as a spatial axis.

The similarity (similarity of the training data in a space having the first axis based on the first data and the second axis based on the second data as reference axes) of the first data in which the second data is considered may be determined based on at least one of cosine similarity, correlation coefficient, and linear regression model evaluation method based on a residual. The residual-based linear regression model evaluation method may use at least one of coefficient of determination (R2 score), Mean Squared Error (MSE), Root Mean Squared Error (RMSE), Mean Absolute Error (MAE), and Residual Sum of Squares (RSS).

The similarity of the first data in which the second data is considered may be determined by the similarity between the plurality of pieces of training data in which the second data is considered.

The similarity of the first data in which the second data is considered may be determined based on a distribution tendency of a plurality of pieces of training data in which the second data is considered.

The similarity of the first data in which the second data is considered may be determined based on the similarity between a plurality of pieces of training data located in a space having a first axis (based on the first data) and a second axis (based on the second data) as reference axes.

A method of refining training data according to an embodiment of the disclosure will be described in detail with reference to FIGS. 6 to 8.

In operation S510, the learning apparatus dimensionally reduces the spatial dimension of the plurality of parameters of the first data to a low-dimensional space.

For example, referring to FIGS. 7A and 7B, the learning apparatus performs a principal component analysis (PCA) on first data 710. The learning apparatus dimensionally reduces the first data 710 to a space having some of the plurality of principal components determined in the PCA as basic axes. The learning apparatus converts the first data 710 into first data 720 in a dimensionally reduced space. The dimensionally reduced space may be a space having a first principal component PC1, which is a component having the greatest variance of the first data 710, and a second principal component PC2 orthogonal to the first principal component PC1 as basic axes.

The following description will be illustratively described on the premise that the first data is reduced to a two-dimensional plane based on the PCA. However, it is not excluded that the first data is dimensionally reduced by other methods such as singular vector decomposition (SVD), non-negative matrix factorization (NMF), and partial least squares (PLS). In addition, it is not excluded that the first data is dimensionally reduced to a space of a dimensional higher than two-dimensional rather than two-dimensional.

FIG. 7B illustrates that the first data 720 is located in a space having the first principal component PC1 and the second principal component PC2 as basic axes.

The learning apparatus may map second data based on a separate axis ST to the first data 720 in the low-dimensional space. The mapping of the second data to the first data 720 and 730 of FIGS. 7B to 7F is illustrated as the contrast of the first data 720 and 730.

In operation S520, the learning apparatus according to the embodiment of the disclosure determines a search vector SV in a low-dimensional space. A method of determining the search vector SV will be described in detail below.

In operation S531, the learning apparatus according to the embodiment of the disclosure projects the first data on the search vector SV.

Referring to FIGS. 7D, 7E, and 7F, the learning apparatus generates first projection data 730 by projecting the first data 720 of a dimensionally reduced low-dimensional space on the search vector SV of the low-dimensional space.

In operation S540, the learning apparatus according to the embodiment of the disclosure refines the training data based on the similarity of the first projection data 730 in which the second data is considered. In an embodiment, the learning apparatus refines the training data based on the similarity of the training data in a space having the axis based on the first projection data 730 and the axis based on the second data as reference axes of the space. The learning apparatus refines the training data based on the similarity of the training data in a space having an axis based on the search vector SV and an axis based on the second data as reference axes of the space.

For example, referring to FIGS. 7E and 7F, the training data 730 exists on the search vector SV located on a dimensionally reduced 2D plane based on the first data 720. The first projection data 730 in which the second data is considered may be located in a space having the axis based on the search vector SV and the axis ST based on the second data as reference axes.

The learning apparatus may determine the similarity of the training data 730 in a space having the axis based on the search vector SV and the axis ST based on the second data as reference axes.

For example, referring to FIG. 7F, among the training data 730 located in a space having the axis based on the search vector SV and the axis ST based on the second data as reference axes, some training data 731 is determined to have low similarity with other training data 732, 733, 734, 735, and 736. Accordingly, some of the training data 731 may be excluded from the final set of the training data.

The similarity of the training data may be determined based on at least one of cosine similarity, a correlation coefficient, and a linear regression model evaluation method based on a residual between each data included in the training data.

For example, referring to FIG. 8, the learning apparatus according to an embodiment of the disclosure may determine the similarity of the training data based on the cosine similarity of data 901, 902, 903, 904, and 905 located in a space that a first axis (X-axis) and a second axis (Y-axis) represent, as follows.

The cosine index of the data 901 is calculated as an average of the cosine distances between the data 901 and each of the remaining data 902, 903, 904, and 905.

The cosine index of the data 902 is calculated as an average of the cosine distances between the data 902 and each of the remaining data 901, 903, 904, and 905.

As in the above description, cosine indices of the remaining data 903, 904, and 905 are calculated.

The standard deviation of the cosine indices of all data 901, 902, 903, 904, and 905 is obtained. A value obtained by dividing each cosine index of each of data 901, 902, 903, 904, and 905 by the standard deviation of all cosine indices is determined as a distribution of the each of data 901, 902, 903, 904, and 905. Data having a distribution greater than or equal to a preset criterion is determined as data with low similarity. The data having a distribution greater than or equal to a preset criterion may be excluded from the final set of the training data.

Similarity of training data based on the correlation coefficient and the linear regression model evaluation method based on a residual may also be determined similarly to cosine similarity.

As an optional embodiment, in operation S532, the learning apparatus according to the embodiment of the disclosure scales the first projection data 730 based on the second data.

Referring to FIGS. 7F and 7G, the learning apparatus generates first projection scaling data 740 obtained by scaling the first projection data 730 based on the second data. The learning apparatus may scale a projected distance of the first projection data 730 within a range of the second data. The projected distance is the distance from the reference point of the search vector SV to each of the first projection data 730. The scaling may be performed in various ways such as MIN-MAX scaling.

One axis of the first projection scaling data 740 may be obtained by scaling the range of the axis on the search vector SV to the range of the second data. Referring to FIG. 7F, projected distances of the remaining training data 731, 733, 734, 735, and 736 are calculated similarly to the projected distance on the search vector SV of the training data 732. The learning apparatus scales the projected distance on the search vector SV of all the training data 731, 732, 733, 734, 735, and 736 within the range of the second data, and each of the training data 741, 742, 743, 744, 745, and 746 may be located in a space having the scaled axis as one of the basic (reference) axes as illustrated in FIG. 7G.

In operation S540, the learning apparatus according to the embodiment of the disclosure refines the training data based on the similarity of the first projection scaling data 740 in which the second data is considered. In an embodiment, the learning apparatus refines the training data based on the similarity of the training data in a space having the axis based on the first projection scaling data 740 and the axis ST based on the second data as reference axes of the space.

Referring to FIG. 7G in detail, the learning apparatus may refine the training data based on the similarity of the training data 741, 742, 743, 744, 745, and 746 scaled based on the second data.

The learning apparatus may identify that other training data 741, 742, 743, 744, and 745 have a similar directionality except for the training data 746 among the first projection scaling data 741, 742, 743, 744, 745, and 746 scaled based on the second data. The learning apparatus may determine a final set of the training data by excluding data 746 having a preset distribution or more based on the cosine similarity between the first projection scaling data 741, 742, 743, 744, 745, and 746 scaled based on the second data.

The training data refinement method according to the embodiments of the disclosure described with reference to FIGS. 6 to 8 is based on the similarity of the training data in which the reference data of the first data is considered, unlike conventional methods that only consider the distribution of the first data. Refinement of the training data may be performed in a space having the first axis based on the first data and the second axis ST based on the second data as reference axes. The first axis based on the first data may be an axis scaled within a range of the second data.

Accordingly, the learning apparatus may exclude training data having a low similarity among a plurality of pieces of training data in a space having the first axis based on the first data and the second axis ST based on the second data as reference axes. As a result, the similarity and consistency of the training data are improved and the prediction accuracy of the learning model is improved compared to the training data refined based only on the first data.

A method of determining the search vector SV will be described with reference to FIGS. 7B and 7C.

The learning apparatus sets an arbitrary vector SV_TEMP in a low-dimensional space in which the first data 720 is dimensionally reduced. The learning apparatus rotates the vector SV_TEMP in all directions of the low-dimensional space. The learning apparatus determines projected data in which the first data 720 is projected for each vector SV_TEMP in each rotated direction. The learning apparatus determines the vector SV_TEMP (e.g., it may be to add the cosine similarity of the first projection data in each direction in which the second data is considered.) having the highest similarity among vectors SV_TEMP in each direction as the search vector SV based on the similarity of projection data in each direction in which the second data is considered.

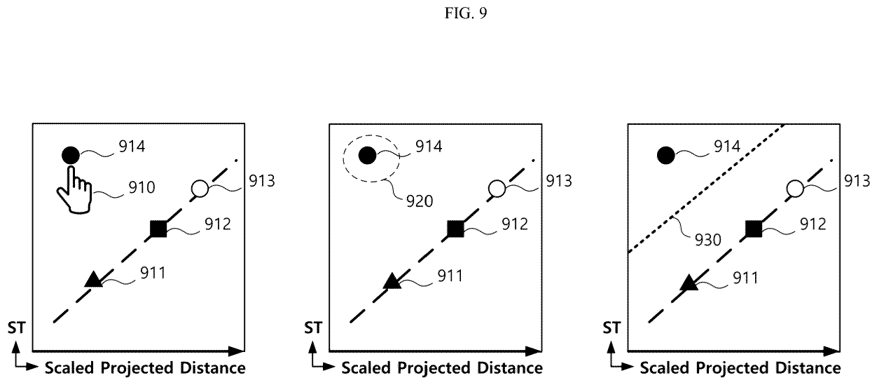

FIG. 9 illustrates a method of refining training data based on a user input of a learning apparatus, according to an embodiment of the disclosure.

A learning apparatus according to an embodiment of the disclosure visualizes a process of refining training data and receives a user's input with respect to the visualization. The learning apparatus refines the training data based on the user's input.

Referring to FIG. 9, the training data is displayed on a display. The training data is located in a space, which is a basic space, having a first axis (based on a scaled projected distance) and a second axis (based on second data which is reference data) as reference axes of the space.

The learning apparatus may receive a touch input 910 for specific training data 914, a setting input 920 for a figure including the specific training data 914, and a division line input 930 between the specific training data 914 and the remaining training data 911, 912, and 913 from a user. The learning apparatus excludes the training data 914 specified by the user's inputs 910, 920, and 930 from the final set of the training data.

Since the refinement method according to the embodiments of the disclosure is performed based on the similarity of the training data in which the reference data of the first data is considered, it is possible to clearly distinguish the training data having a low similarity. Since the refinement method according to the embodiments of the disclosure is performed based on the similarity of the training data in a space having the first axis (based on the first data) and the second axis ST (based on the second data) as reference axes, the training data having low similarity may be clearly distinguished. Therefore, the user may intuitively identify the similarity of the training data.

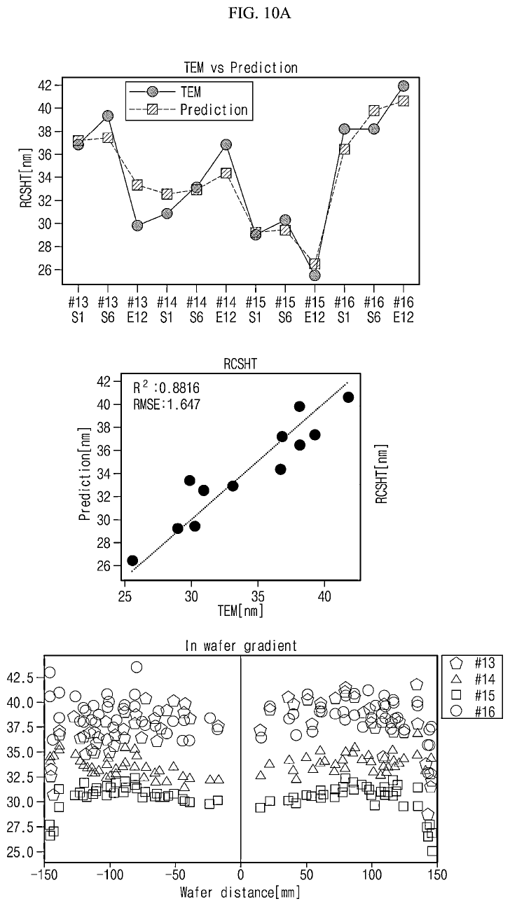

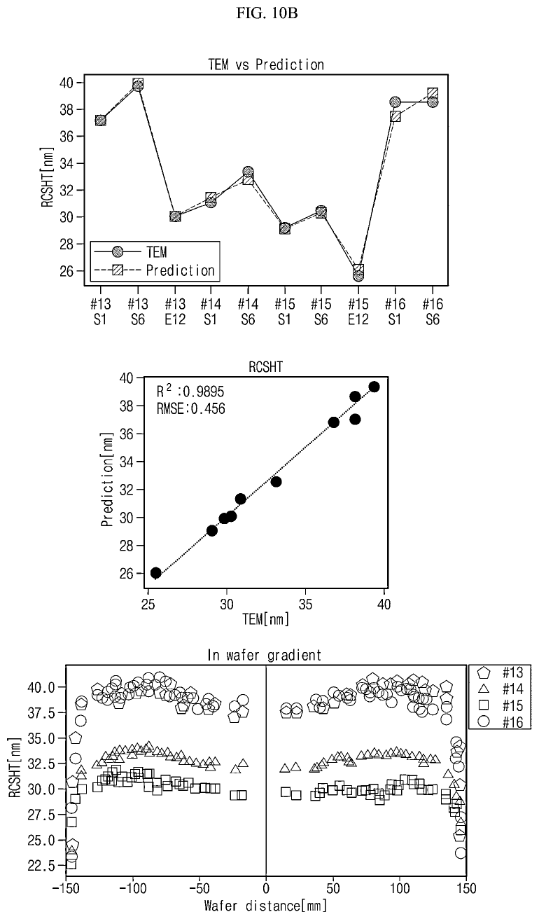

FIG. 10A and FIG. 10B illustrate the prediction accuracy for a recess depth RCSHT of the structure of the wafer of the learning model trained by the refined training data, according to the embodiment of the disclosure.

FIG. 10A is an experimental result of a learning model trained with 12 pieces of unrefined training data. FIG. 10B is an experimental result of a learning model trained with 10 pieces of refined training data, according to an embodiment of the disclosure.

Referring to FIGS. 10A and 10B, it may be seen that the predicted value of the recess depth RCSHT of the refined learning model, according to the embodiment of the disclosure is remarkably similar to the value of a recess depth actually confirmed in the TEM image compared to the unrefined case.

Referring to FIGS. 10A and 10B, it may be seen that the RMSE value (0.456), which is an error value associated with the recess depth prediction of the refined learning model according to the embodiment of the disclosure, is much lower than that of the unrefined case (1.647).

Referring to FIGS. 10A and 10B, it may be seen that a value (0.9895) of a determination coefficient (R2) associated with the recess depth prediction of the refined learning model according to the embodiment of the disclosure is much closer to ‘1’ than that of the unrefined case (0.8816).

According to an embodiment of the disclosure, a learning model for predicting a structure of a semiconductor device and an apparatus for predicting the structure of the semiconductor device may improve the prediction accuracy of a structure of a semiconductor device based on metrology data.

According to an embodiment of the disclosure, a learning model for predicting a structure of a semiconductor device and an apparatus for predicting the structure of the semiconductor device may improve the consistency of the training data by refining the training data that is not suitable for training in a process of training a model for predicting the structure of the semiconductor device.

Meanwhile, the above descriptions are specific embodiments for carrying out the disclosure. Embodiments in which a design is changed simply or which are easily changed may be included in the disclosure as well as an embodiment described above. In addition, technologies that are easily changed and implemented using the above embodiments may be included in the disclosure. While the disclosure has been described with reference to embodiments thereof, it will be apparent to those of ordinary skill in the art that various changes and modifications may be made thereto without departing from the spirit and scope of the disclosure as set forth in the following claims.

What is claimed is:

1. An apparatus for predicting a structure of a semiconductor device, the apparatus comprising:
a storage configured to store a learned model configured to predict the structure of the semiconductor device;
a memory configured to store at least one code, and
at least one processor operatively connected to the memory and configured to execute the at least one code to:
input non-destructive metrology data measured from the semiconductor device into the learned model, and
predict the structure of the semiconductor device, based on the learned model,
wherein the learned model is trained with training data including first data which is non-destructive metrology data and second data which is structural metrology data as reference data of the first data, and
wherein the training data is refined based on a similarity of the training data in a space having a first axis corresponding to the first data and a second axis corresponding to the second data as reference axes.

2. The apparatus of predicting the structure of the semiconductor device of claim 1, wherein the first data is metrology data of the semiconductor device based on spectrum, and the second data is structure data obtained by measuring at least a part of the structure of the semiconductor device.

3. A method of generating a learned model configured to predict a structure of a semiconductor device, the method comprising:
identifying training data comprising:
first data which is non-destructive metrology data of the semiconductor device, and
second data which is structure data as reference data of the first data;
refining the training data based on a similarity of the training data in a first space having a first axis corresponding to the first data and a second axis corresponding to the second data as first reference axes; and
training a learning model based on the refined training data.

4. The method of claim 3, wherein the first axis is scaled within a range of the second data.

5. The method of claim 3, wherein the first data is spectrum-based metrology data of the semiconductor device, and the second data is obtained by measuring at least a part of the structure of the semiconductor device.

6. The method of claim 3, wherein the refining the training data comprises:
determining a search vector in a low-dimensional space in which the first data is dimensionally reduced; and
refining the training data in a second space represented by a third axis corresponding to the search vector and a fourth axis corresponding to the second data.

7. The method of claim 6, wherein the search vector is a vector in which the training data has a highest similarity in the second space among arbitrary vectors in the low-dimensional space in which the first data is dimensionally reduced.

8. The method of claim 6, wherein the third axis corresponding to the search vector is scaled based on the second data.

9. The method of claim 6, wherein the search vector is a vector in the low-dimensional space in which the first data is dimensionally reduced based on at least one of principal component analysis (PCA), singular vector decomposition (SVD), non-negative matrix factorization (NMF), and partial least squares (PLS).

10. The method of claim 6, wherein the refining the training data comprises visualizing by displaying the training data in the second space represented by the third axis corresponding to the search vector and the fourth axis corresponding to the second data.

11. The method of claim 10, wherein the refining the training data comprises:
receiving an input of a user with respect to a visualized result; and
refining the training data based on the input of the user.

12. The method of claim 3, wherein the similarity is based on at least one of cosine similarity, a correlation coefficient, and a linear regression model evaluation method based on a residual of the training data in the first space.

13. An apparatus of generating a learning model configured to predict a structure of a semiconductor device, the apparatus comprising:
a memory configured to store at least one code; and
at least one processor operatively connected to the memory and configured to execute the at least one code to:
train the learning model with training data including:
first data which is non-destructive metrology data measured from the semiconductor device, and
second data which is structure data as reference data of the first data, and
refine the training data based on a similarity of the training data in a first space having a first axis corresponding to the first data and a second axis corresponding to the second data as first reference axes.

14. The apparatus of claim 13, wherein the first axis is scaled within a range of the second data.

15. The apparatus of claim 13, wherein the at least one processor is configured to execute the at least one code to:
determine a search vector in a low-dimensional space in which the first data is dimensionally reduced, and
refine the training data in a second space having a third axis corresponding to the search vector and a fourth axis corresponding to the second data as second reference axes.

16. The apparatus of claim 15, wherein the search vector is a vector in which the training data has a highest similarity in the second space among arbitrary vectors in the low-dimensional space in which the first data is dimensionally reduced.

17. The apparatus of claim 15, wherein the third axis corresponding to the search vector is scaled based on the second data.

18. The apparatus of claim 15, wherein the at least one processor is configured to execute the at least one code to visualize by displaying the training data in the second space having the third axis corresponding to the search vector and the fourth axis corresponding to the second data as the second reference axes.

19. The apparatus of claim 18, the at least one processor is configured to execute the at least one code to:
receive an input of a user with respect to a visualized result, and
refine the training data based on the input of the user.

20. The apparatus of claim 13, wherein the similarity is based on at least one of cosine similarity, a correlation coefficient, and a linear regression model evaluation method based on a residual of the training data in the first space.
